(19) United States
(12) Patent Application Publication
(10) Pub. No.: US 2005/0224883 A1
(43) Pub. Date: Oct. 13, 2005

(54) Circuit design for increasing charge device model immunity

(75) Inventors: Shao-Chang Huang, Hsin-chu (TW); Shu-Chuan Lee, Hsin-chu city (TW)

Correspondence Address: DUANE MORRIS LLP;IP DEPARTMENT (TSMC), 4200 ONE LIBERTY PLACE, PHILADELPHIA, PA, 19103-7396, US

(73) Assignee: Taiwan Semiconductor Manufacturing Company, Ltd.

(21) Appl. No.: 10/819,759

(22) Filed: Apr. 6, 2004

(51) Int. Cl. H01L 23/62

(52) U.S. Cl. 257/355

(57) ABSTRACT

A charge device model (CDM) immunity module used in a semiconductor circuit for CDM damage protection. The CDM immunity module comprises a CDM ground pad and a current directing device such as a diode coupled between the CDM ground pad and a substrate of at least one device in a core circuit to be protected, wherein the current directing device and the CDM ground pad dissipate CDM charges to avoid damage to an oxide layer of the protected device.

### BACKGROUND

The present invention relates generally to semiconductor devices, and more particularly, to electrostatic discharge (ESD) protection of CMOS semiconductor devices from charge device model (CDM) discharges. Still more particularly, the present invention relates to the circuits and methods used to protect semiconductor devices from the destructive effects of the charge device model discharges internal to the semiconductor device.

During manufacturing, testing and handling of semiconductor devices such as integrated circuits (ICs), damage may occur due to electrostatic discharge (ESD) events. An electrostatic charge may be generated by people or machines handling the semiconductor devices. This electrostatic charge could be transferred into the semiconductor device via the external pins, to the internal bond pads, and into the semiconductor device internal circuitry causing severe damage. This phenomenon is well understood for all the generation semiconductor technologies. The “human body model” (HBM) and the “machine model” (MM) are embodiments of the models in which discharges occur through a resistive path. Circuit protection measures have been successfully applied to largely eliminate semiconductor failures due to these mechanisms.

For the current and future semiconductor fabrication technologies, faster discharges through low resistive paths called “a charge device model” (CDM) has emerged as a new ESD event. The charge device model represents a discharge from a semiconductor device rather than to it. If a semiconductor device's internal circuitry becomes charged as a result of the fabrication processes being used to manufacture it, a rapid discharge of the stored energy internal to the device may occur to an external conductor, such as a work surface or fabrication equipment. The rapid discharge (typically 1 nanosecond and tens of amperes of current) of this stored charge may have destructive consequences to the semiconductor device during manufacture and may result in a non-operational semiconductor device after fabrication has been completed. Similarly, a charged semiconductor device placed on a conductive work surface will discharge rapidly through the work surface, possibly damaging the semiconductor device's internal circuitry. The type of failure generated is similar to an HBM or MM event, but the key difference is that the entire device is charged to a high voltage and then discharged to ground. Therefore, the ESD energy may travel in paths different than the paths in the HBM or the MM during the discharge time. Also, because of the wider bandwidth of modern semiconductor devices, the standard ESD protection methods are less effective and may limit the performance of the semiconductor device.

Additional protection schemes are necessary to protect semiconductor device ESD damage due to the destructive effects of the charge device model (CDM) event.

### SUMMARY

A circuit and method to increase the semiconductor device internal circuitry immunity from charge device model (CDM) destructive effects.

A charge device model (CDM) immunity module is used in a semiconductor circuit for CDM damage protection. The CDM immunity module comprises a CDM ground pad and a current directing device such as a diode coupled between the CDM ground pad and a substrate of at least one device in a core circuit to be protected, wherein the current directing device and the CDM ground pad dissipate CDM charges to avoid damage to an oxide layer of the protected device.

The construction and method of operation of the invention, however, together with additional objects and advantages thereof, will be best understood from the following description of specific embodiments when read in connection with the accompanying drawings.

### BRIEF DESCRIPTION OF THE DRAWINGS

FIG. 1 illustrates a conventional semiconductor circuit with standard ESD protection.

FIG. 2 illustrates a CDM immunity circuit in accordance with a first embodiment of the present invention.

FIGS. 3A-3C illustrate the fabrication process of the CDM immunity circuit in accordance with the first embodiment of the present invention.

FIG. 4 illustrates a CDM immunity circuit in accordance with a second embodiment of the present invention.

FIG. 5 illustrates a CDM immunity circuit in accordance with a third embodiment of the present invention.

FIG. 6 illustrates a CDM immunity circuit in accordance with a fourth embodiment of the present invention.

FIG. 7 illustrates a CDM circuit layout within the semiconductor device applicable to the first through the fourth embodiments of the present invention.

### DESCRIPTION

In the present invention, embodiments of the circuit and method are disclosed to provide increased immunity to the semiconductor device's internal circuitry from the charge device model (CDM) destructive effects.

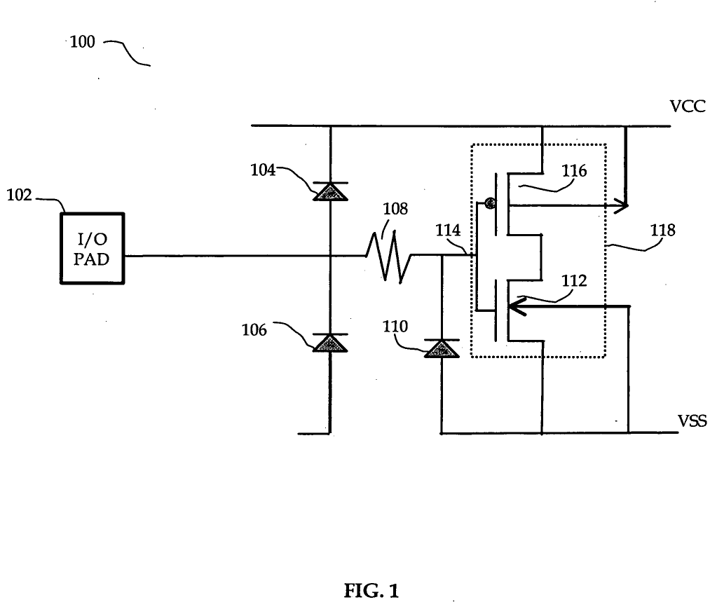

FIG. 1 illustrates a conventional semiconductor circuit 100 with standard ESD protection for the ESD effects in the human body model (HBM), the machine model (MM), and the limited CDM. The circuit is connected to an external pin on the case of the semiconductor device via the I/O pad 102. This connection to the outside environment provides a path for ESD conduction that could possibly damage the semiconductor device. Therefore, diodes 104 and 106 are utilized to protect the internal circuitry from the ESD effects of the HBM and the MM by shorting the electrostatic pulses to either VCC or VSS, respectively. A resistor 108 provides a current limiting and isolation effect to the core circuitry. A diode 110 provides partial protection from the charge device model CDM effects on a NMOS transistor 112 gate oxide layer by shunting the CDM ESD pulses to ground rather than applying it via line 114 to the gate oxide layer of the NMOS transistor 112. The NMOS transistor 112 and a PMOS transistor 116 form a typical MOS buffer circuit 118, which is shown here to represent a core circuitry of the IC. If a CDM ESD pulse were applied across the gate oxide layer of transistors 112 and 116, possible degradation or destruction of the transistors may occur, thereby rendering the entire semiconductor device degraded or inoperable during the fabrication process.

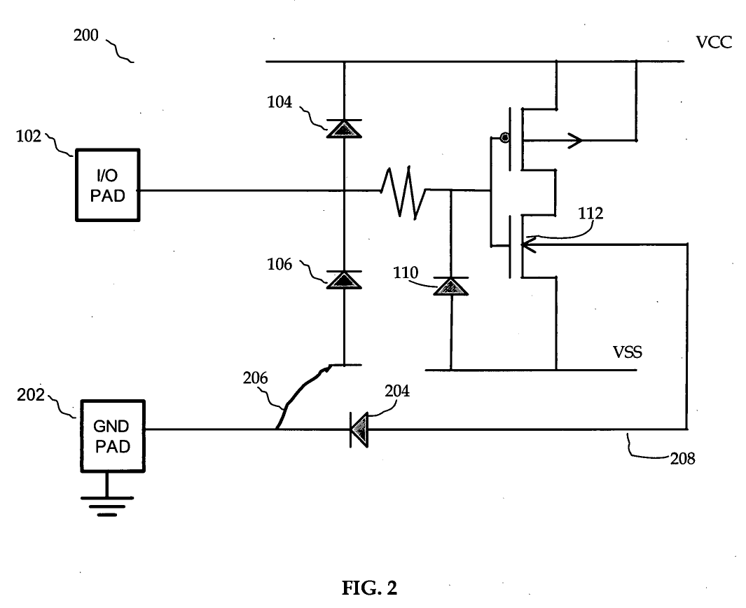

FIG. 2 illustrates a CDM immunity circuit 200 in accordance with a first embodiment of the present invention. The CDM immunity circuit 200 is similar to the conventional circuit 100, except that a CDM immunity module has a ground pad 202 and a current directing device such as a diode 204 is added to provide additional CDM immunity to the semiconductor device circuitry. In order to distinguish it from other regular ground pads that the device circuitry may have, the ground pad 202 may be referred to as a CDM ground pad as it is dedicated for grounding charges or currents caused by the CDM effect. The CDM ground pad 202 is fabricated into the semiconductor device and connected to the device ground. The anode of the diode 106 may also be connected to the CDM ground pad 202 (ground), as shown by a line 206, for enhanced ESD protection. The cathode of the diode 204 is tied to the CDM ground pad 202 while the anode is tied via a line 208 to the P type substrate of the transistor 112. The diode 204 conducts any CDM charge buildup on the P type substrate directly to ground, thereby preventing damage to the gate oxide layer due to CDM ESD events. The diode 204 should be designed to utilize as large an area as possible in the semiconductor device to absorb as large a CDM charge as possible. The diodes 204 and 110 together provide a more complete protection of the NMOS transistor 112 from CDM discharges. The diodes 104 and 106 provide protection from HBM and MM ESD charges as explained in connection with FIG. 1. It is noted that the existence of transistor 110 is optional when the CDM charges are now directed through a different route.

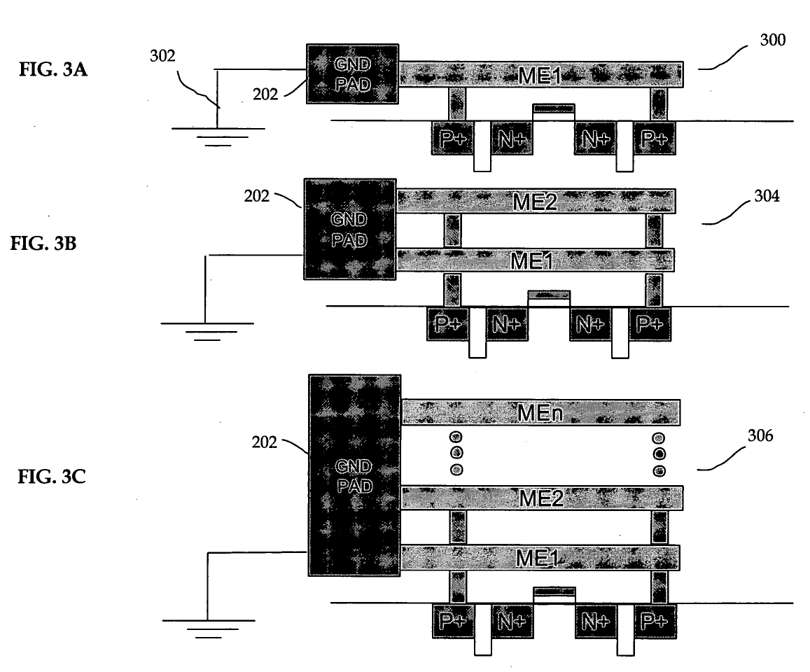

FIG. 3A presents a drawing 300 illustrating the actual connection of the CDM ground pad 202 to the first metal layer (ME1) of the semiconductor device in accordance with the first embodiment of the present invention. CDM ground pad 202 is also connected to the semiconductor device ground via a line 302. When the first metal layer is connected to the CDM ground pad 202, hence ground, all CDM charges in the substrate that are generated by previous fabrication processes will be shorted to ground. This eliminates the possibility of circuit damage from CDM effects due to fabrication processes thus far.

FIG. 3B presents a drawing 304 illustrating the actual connection of the CDM ground pad 202 to the second (ME2) and the first metal layers of the semiconductor device in accordance with the first embodiment of the present invention. When the second metal layer is connected to CDM ground pad 202, hence ground, all CDM charges in the substrate that are generated by the previous fabrication processes will be shorted to ground.

FIG. 3C presents a drawing 306 illustrating the actual connection of the CDM ground pad 202 to the last (MEn) and all previous metal layers of the semiconductor device in accordance with the first embodiment of the present invention. When the metal layer MEn is connected to CDM ground pad 202, hence ground, all CDM charges in the substrate that are generated by the previous fabrication processes will be shorted to ground. This eliminates the possibility of circuit damage from CDM effects due to any of the fabrication processes.

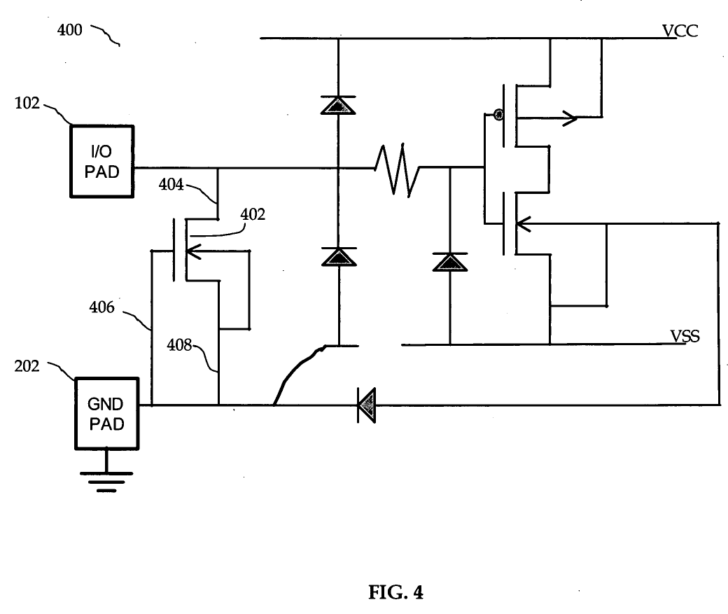

FIG. 4 illustrates a CDM immunity circuit 400 in accordance with a second embodiment of the present invention. The circuit 400 is similar to the circuit 200 except that a NMOS transistor 402 is connected between two pads 202 and the I/O pad 102. The NMOS transistor 402 is a grounded gate configuration with the drain tied to the I/O pad 102 via a line 404, the gate tied to pad 202 via a line 406, and the source tied to pad 202 via a line 408. The transistor 402 provides protection from ESD events between the pad 202 and the I/O pad 102 in HBM and MM by dissipating ESD charges. The CDM ground pad 202 is grounded during the normal condition of the IC. In a multiple I/O pad scenario, all I/O pads 102 may be tied to a ground pad through a grounded gate NMOS transistor to provide additional protection from HBM and MM events. This ESD/CDM protection circuit can be placed in a corner or feeder cell of the IC for efficient layout thereof.

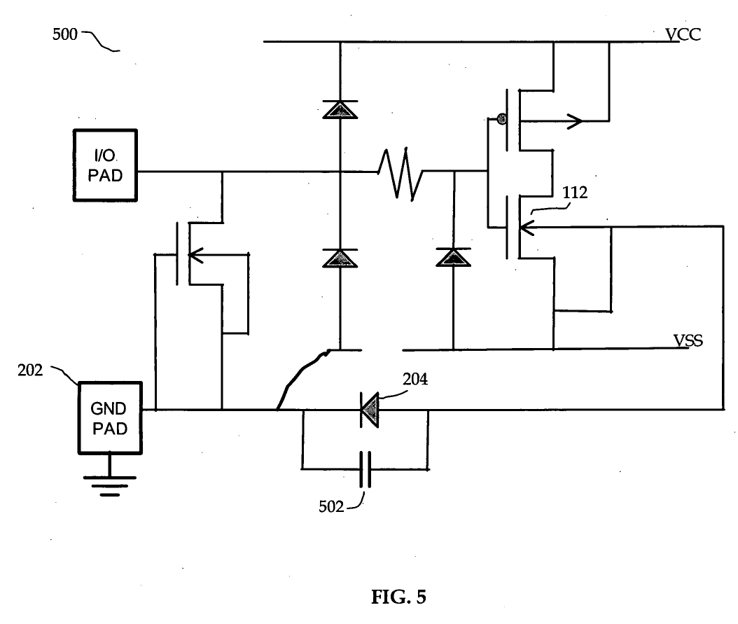

FIG. 5 illustrates a CDM immunity circuit 500 in accordance with a third embodiment of the present invention. The circuit 500 is similar to the circuit 400 except that a capacitor 502 is added. The capacitor 502 is placed in parallel with the diode 204 to assist in the ESD protection performance in the CDM. In this configuration, capacitor 502 can absorb additional charges from the substrate of the transistor 112, thereby reducing the substrate current. When the capacitor 502 voltage increases above the turn-on voltage of the diode 204, the diode will conduct current to the CDM ground pad 202. In addition, by storing the CDM charges in the capacitor 502, it also reduces the charges loaded on other parts of the circuit.

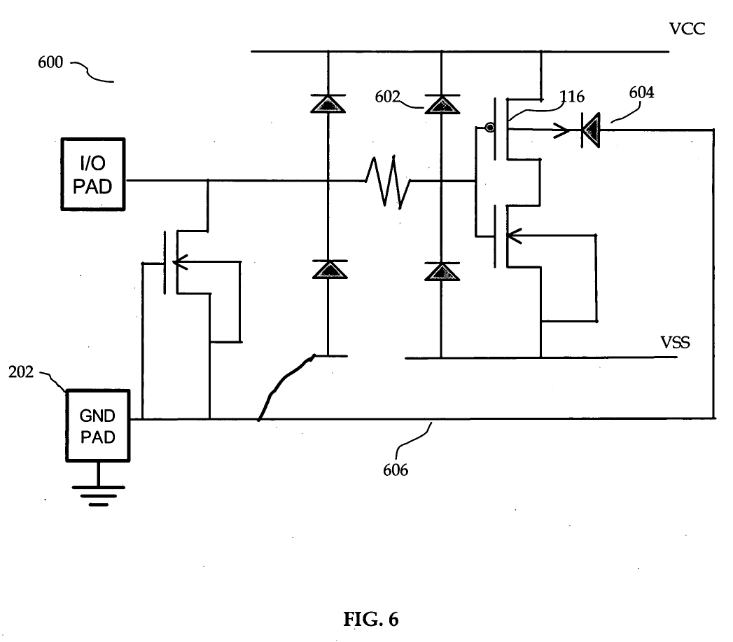

FIG. 6 illustrates a CDM immunity circuit 600 in accordance with a fourth embodiment of the present invention. The circuit 600 is similar to the circuit 400 except that CDM ESD protection is added to the N type substrate of the PMOS transistor 116. A diode 602 is added to protect the gate oxide layer of the PMOS transistor 116 from CDM effects. This diode 602, like the diode 110, is optional. The cathode of a diode 604 is connected to the N type substrate of the transistor 116 while the anode is connected to the CDM ground pad 202 via a line 606. With reference to FIGS. 4 and 6, it is noted that, in comparison with the diode 204, the diode 604 is connected in opposite polarity due to the opposite polarity of the substrate of, and the reverse current flow for the PMOS transistor 116. In other words, the circuit 600 will provide CDM ESD protection for the PMOS transistor 116 similar to the protection for the NMOS transistor 112 in the circuit 400.

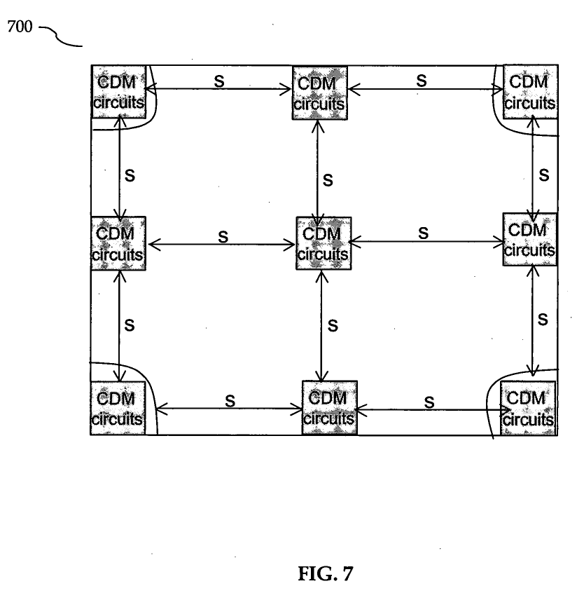

FIG. 7 illustrates a CDM circuit layout 700 within the semiconductor device applicable to the first through the fourth embodiments of the present invention. The CDM circuits are located in the unused semiconductor device corner cells to minimize areas required for the CDM circuits. In addition, the CDM circuits may be spaced equally (distance S) within the semiconductor device to insure that the CDM charges will be dissipated within the CDM circuit and not through the semiconductor device's internal circuitry. This will minimize potential CDM ESD damage to the semiconductor device's internal circuitry during fabrication.

The foregoing, thus, provides embodiments of circuits and methods to add additional circuit components internally to an IC to reduce the charge device model's destructive effects that may occur during the semiconductor device fabrication process steps. These additional components will not require additional masks or process steps that would increase the fabrication costs. The addition of the grounding pads will connect each metal layer as they are deposited in the fabrication process. The grounding pad will be connected to each completed metalization layer to discharge any CDM charges prior to the next metalization layer. By insuring that each metal layer is grounded during fabrication, the CDM charge will be dissipated prior to any damage to the oxide layer of a semiconductor MOS device. It may be desirable to ground these pads as many times as possible, and they may be preferred to be grounded before other pads are grounded. Longer pins or leads may be used for the CDM ground pad to increase the possibility that they get grounded first. As ICs may have several ground pads, they can be used as the ground pad disclosed above for CDM purposes.

Although the invention is illustrated and described herein as embodied in a particular circuit, the use of this CDM immunity circuit can apply to any other circuit with, or without, ESD protection circuits.

The above invention provides many different embodiments or embodiments for implementing different features of the invention. Specific embodiments of components and processes are described to help clarify the invention. These are, of course, merely embodiments and are not intended to limit the invention from that described in the claims.

Although illustrative embodiments of the invention have been shown and described, other modifications, changes, and substitutions are intended in the foregoing invention. Accordingly, it is appropriate that the appended claims be construed broadly, and in a manner consistent with the scope of the invention, as set forth in the following claims.

1. A method for providing a charge device model (CDM) damage protection for a semiconductor circuit, the method comprising:
coupling a CDM immunity module to a substrate of at least one device to be protected from the CDM damage; and
coupling the CDM immunity module to a ground pad,
wherein the CDM immunity module and the ground pad dissipate CDM charges to avoid damage to an oxide layer of the device.

2. The method of claim 1 wherein the CDM immunity module is a diode.

3. The method of claim 2 wherein the device is a NMOS transistor and its substrate is connected to the diode's anode.

4. The method of claim 2 wherein the device is a PMOS transistor and its substrate is connected to the diode's cathode.

5. The method of claim 1 wherein the CDM immunity module is a diode coupled parallel with at least one capacitor.

6. The method of claim 1 wherein the ground pad is connected to at least one metalization layer of the device.

7. The method of claim 1 wherein the ground pad is connected to one or more metalization layers of the device as they are processed sequentially for forming the device.

8. The method of claim 1 wherein the CDM immunity module is placed in one or more corner regions of the semiconductor circuit.

9. The method of claim 1 wherein the semiconductor circuit further comprises at least one electrostatic discharge (ESD) protection module in conjunction with the CDM immunity module.

10. The method of claim 9 wherein the ESD protection module is coupled between the ground pad and a regular pad of the semiconductor circuit.

11. The method of claim 10 wherein the ESD protection module is a NMOS transistor with its gate and source connected to the ground pad, and its drain connected to the regular pad.

12. The method of claim 9 wherein the ESD protection module further comprises a diode connected between the gate and source thereof.

13. A semiconductor circuit with charge device model (CDM) damage protection, the circuit comprising:
a CDM immunity module coupled to a substrate of at least one device in a core circuit; and
a CDM ground pad coupled to the CDM immunity module,
wherein the CDM immunity module and the CDM ground pad dissipate CDM charges to avoid damage to an oxide layer of the device.

14. The circuit of claim 13 wherein the CDM immunity module is a diode.

15. The circuit of claim 14 wherein the device is a NMOS transistor and its substrate is connected to the diode's anode.

16. The circuit of claim 14 wherein the device is a PMOS transistor and its substrate is connected to the diode's cathode.

17. The circuit of claim 13 wherein the CDM immunity module is a diode coupled parallel with at least one capacitor.

18. The circuit of claim 13 wherein the CDM ground pad is connected to one or more metalization layers of the device as they are processed for forming the device.

19. The circuit of claim 13 wherein the CDM immunity module is placed in one or more corner regions of the semiconductor circuit.

20. The circuit of claim 13 further comprising at least one electrostatic discharge (ESD) protection module in conjunction with the CDM immunity module, wherein the ESD protection module is coupled between the CDM ground pad and a regular pad of the semiconductor circuit.

21. The circuit of claim 20 wherein the ESD protection module is a NMOS transistor with its gate and source connected to the CDM ground pad, and its drain connected to the regular pad.

22. A charge device model (CDM) immunity module used in a semiconductor circuit for CDM damage protection, the CDM immunity module comprising:
a CDM ground pad; and
a diode coupled between the CDM ground pad and a substrate of at least one device in a core circuit,
wherein the diode and the CDM ground pad dissipate CDM charges to avoid damage to an oxide layer of the device.

23. The module of claim 22 wherein the device is an NMOS transistor and its substrate is connected to the diode's anode.

24. The module of claim 22 wherein the device is a PMOS transistor and its substrate is connected to the diode's cathode.

25. The module of claim 22 further comprising at least one capacitor coupled parallel with the diode.

26. The module of claim 22 wherein the CDM ground pad is connected to one or more metalization layers of the device as they are processed for forming the device.

27. The module of claim 22 wherein the CDM ground pad is a regular ground pad of the semiconductor circuit.
